(19) United States
(12) Patent Application Publication
(10) Pub. No.: US 2016/0017496 A1
(43) Pub. Date: Jan. 21, 2016

(54) Method For Optimizing A Deposition Process, Method For Setting A Deposition System and Deposition System

(71) Applicant: JOHANN WOLFGANG GOETHEUNIVERSITÄT, Frankfurt am Main (DE)

(72) Inventors: MICHAEL HUTH, Usingen (DE); CHRISTIAN SCHWALB, Oberursel (DE); MARCEL WINHOLD, Freigericht (DE); PAUL MARTIN WEIRICH, Wehrheim (DE)

(73) Assignee: JOHANN WOLFGANG GOETHE-UNIVERSITÄT, 60323 Frankfurt am Main (DE)

(21) Appl. No.: 14/773,494

(22) PCT Filed: Mar. 10, 2014
(86) PCT No.: PCT/EP2014/000617

§ 371 Date: Sep. 8, 2015

(30) Foreign Application Priority Data
Mar. 8, 2013 (DE) 10 2013 004 116.3

(51) Int. Cl. C23C 16/52; C23C 16/16; C23C 16/48

(52) U.S. Cl. CPC C23C 16/52; C23C 16/486; C23C 16/487; C23C 16/16

(57) ABSTRACT

A method optimizing a deposition process for creating an electrically conductive layer with an electron or ion beam-induced deposition system, comprising: selecting at least one deposition specific setting parameter of the system; determining several parameter values of at least one setting parameter defining a first generation parameter value population; depositing a layer for each first generation parameter value population using the deposition system; detecting an electrical characteristic for each layer of each parameter value of said parameter value population; using a genetic algorithm to provide an optimization evaluation of the detected characteristics using a predetermined target characteristic, and using said evaluation determining a further generation parameter value population; repeating said deposition step through said determination step by using the parameter values of a second generation or a further generation, until said target characteristic is reached or the genetic algorithm is concluded for a generation predetermined to be the last generation.

The invention relates to a method for optimizing a deposition process, a method for setting a deposition system and a deposition system. The deposition process creates a cohesive, electrically conductive layer in particular having a layer thickness of 20 nm or less, but at least 5 nm. In particular the deposition process to be optimized relates to a mask-free “bottom-up”-method such as focused electron beam- or ion beam-induced deposition for forming a deposition or conductor structure spatially defined in one, preferably two or three spatial directions on the substrate.

From DE 10 2010 055 564 A1, a deposition process of a silicon comprising precursor onto a substrate utilizing a focused electron beam or ion beam is known. In the known method, the precursor is decomposed or dissociated by the particle beam proximate the substrate and thereby a conductive layer is formed.

The article “The transient electrical conductivity of W-based electron-beam-induced deposits during growth, irradiation and exposure to air” by F. Porrati, R. Sachser and M. Huth, published in Nanotechnology on Apr. 20, 2009, describes several experiments in which one respective conductive layer is deposited in a deposition system from a tungsten-hexacarbonyl precursor onto a silicon substrate. In each experiment, setting parameters of the deposition system, such as the dwell time of the electron beam in view of a beam movement raster and the rate of raster position repetition are set to parameter values predetermined in a chart, a conductive layer is deposited and the development of the electrical conductivity during the deposition and during airing of the deposition system is observed.

The complex deposition processes known from the prior art have the disadvantage that it is very time consuming to find suitable deposition parameters which create a conductive layer with the desired electrical qualities. From the multitude of setting parameters of the deposition system follows a vast number of possible parameter combinations, the experimental examination of which occupies several weeks or months, even if limited to values which are known to be expedient, in particular when using new precursors, precursor compositions, mixtures of different precursor species or substrates.

It is an objective of the invention to overcome the disadvantages of the prior art, in particular to provide a method for optimizing a deposition process, a method for setting a deposition system and a deposition system with which the best possible settings for the deposition system can be found in view of a desired electrical quality of a conductive layer to be created as fast as possible and with the least experimental effort.

This objective is solved by the methods and the subject matter of the independent claims.

According to a first aspect of the invention, a method for optimizing a deposition process for creating an electrically conductive layer, preferably having a layer thickness of less than 20 nm, by means of an electron beam- or ion beam-induced deposition system comprises:

Step 1: Selecting at least one deposition specific setting parameter to be optimized, such as an electron beam parameter or ion beam parameter, of the deposition system wherein possibly at least one further setting parameter of the deposition system is kept constant;

Step 2: Determining several parameter values of at least one setting parameter for defining a first generation parameter value population;

Step 3: Depositing one layer for each parameter value of the first generation parameter value population by means of a deposition system;

Step 4: Detecting an electrical characteristic for each layer of each parameter value of the first generation parameter value population;

Step 5: Using a genetic algorithm which executes an optimization evaluation of the detected electrical characteristics with respect to a predetermined electrical target characteristic and which determines, based on the optimization evaluation, a further second generation parameter value population; and

Step 6: Repeating the steps 3 to 5 under the premise of the use of parameter values of the second or possibly a further generation, until the electrical target characteristic is reached or until the genetic algorithm is concluded for the generation predetermined to be the last generation. In particular, the method is conducted or performed for at least 10 generations.

Preferably the deposition process is optimized such that the electrical conductivity of the created conductive layer is maximal or as close as possible to the predetermined target conductivity.

Preferably the layer is deposited according to step 3 with the aid of a focused electron beam or ion beam. In particular, the electron beam or ion beam comprises a focus area having a diameter of about 5 nm or less. In particular, the electrical characteristic of each layer is determined or quantified by particularly directly measuring the layer. Preferably the measurement is made in-situ, that is the electrically conductive layer remains within the deposition system, preferably in an unchanged position, during the measurement. In particular, the process conditions, such as temperature and pressure, remain constant within the deposition system during the detection of the electrical characteristic.

It has been shown that, with the aid of the method according to the invention, parameter values optimized with respect to the desired layer quality can be found even in large value ranges for setting parameters of the deposition system whilst decreasing the time effort to a few hours. Furthermore, using the invention, also influence factors or combinations of influence factors or setting parameters for optimizing the deposition process are accessible for which no experience value or model is available.

In particular when using the genetic algorithm for optimization evaluation of the electrical characteristics of the respective layer, a fitness is assigned in proportion to the achieved electrical characteristic. In particular the assessment is done such that the electrical characteristic becomes maximal. The fitness of a layer is calculated as the ratio of the electrical characteristic value of the respective layer to the sum of the electrical characteristics of all layers of the same population. The evaluation of the electrical characteristics of the layers of a parameter value population occurs according to a known selection algorithm, such as fitness proportional selection, rank based selection, competitive selection, the roulette principle or the so called Stochastic Universal Sampling. With the aid of the evaluation, a group of parameter values is determined which serve as basis for the determination of the parameter value population of a further generation. The group comprises the parameter values having a higher fitness more often, in particular proportionally more often in relation to the fitness, than parameter values having a lower fitness.

In order to obtain a random, minor scattering around the selected parameter values, these are combined according to crossing procedures such as One-Point-Cross-Over, N-Point-Cross-Over, Template-Cross-Over, Uniform-Cross-Over or Shuffle-Cross-Over. Subsequently, for avoiding local maxima, at least one of the parameter values can be mutated according to a predeterminable chance so that new parameter values can be introduced in comparison to the crossing which also allows for a larger change of the parameter values. As a result, several parameter values of a further generation's population are obtained. Preferably, the size of a population is equally large for all generations throughout the entire method. In particular the parameter values for the first population are randomly selected within an allowable value range.

In a further development of the invention, several system specific setting parameters to be optimized, in particular all setting parameters, are selected. In particular, in a first generation population of size N, N different parameter value combinations are determined for several setting parameters. The method according to the invention is performed in the same way, wherein for the optimization evaluation it is to be taken into account that a combination of parameters is assigned to the electrical characteristic of the respective layer which is used according to the genetic algorithm for determining the next generation of parameter value combinations.

According to a further development of the invention, the at least one setting parameter is selected from a group comprising: an accelerating voltage of the electron beam or ion beam, a current of the electron beam or ion beam, a defocus of the electron beam or ion beam, a raster pitch of the movement raster of the electron beam or ion beam, a raster position dwell time, a rate of raster position repetition, a temperature of the substrate on which the layers are deposited, a precursor gas stream and a chemical composition of a precursor under the dissociation of which the layers are deposited.

In particular the movement raster of the electron beam or ion beam is laid out in the shape of serpentine roads, spirally shaped starting at the central position of the substrate, or intermittent (for instance: large step forwards, small step backwards) in relation to a substrate layer. Preferably the raster position of the dwell time of the electron beam or ion beam is between 0.01 μs and 10 ms. Preferably the raster pitch is between 1 nm and 1 μm. Particularly the pitch of the raster in x-direction and perpendicular thereto in y-direction is equal. Preferably the pitch of the raster in x-direction and the pitch of the raster in y-direction are selected as setting parameters to be optimized and are optimized simultaneously. It has been shown that, with the aid of this, parameter values are found with little experimental effort which create very high conductivity values in the deposited structures, since mutual influences through changes of the parameter values are immediately taken into account in the result. Particularly the rate of raster position repetition is fixed or defined by the time period between the first irradiation of a raster position and a second irradiation of a raster position during the deposition of one layer.

The accelerating voltage is preferably in a range of 1 kV to 100 kV. The beam current is preferably in the range of 0.1 pA to 10 μA.

In a preferred development, the parameter value specific layers of a respective parameter value population and/or the generations of parameter value populations are deposited electrically in parallel to one another. In particular, the layers are deposited onto the substrate overlapping one another, so that the electrical connection for the parallel circuiting is formed between the layers.

In a further development of the invention, the parameter value specific layers of the respective parameter value population and/or the parameter value populations are deposited one above another. In particular, through depositing above one another, a sandwich-like multiple-layer-structure is formed, wherein in particular all layers of the multiple-layer-structure contact one another electrically. By layering above one another, experiments with large population sizes and large number of generations can be formed on a relatively little substrate area and thus the conditions within the deposition system can be kept constant as long as possible.

In a further development of the invention, a respective layer is deposited between two measuring electrodes and/or a respective parameter value population or parameter value specific multiple-layer-structure is deposited between two respective generation specific measurement electrodes. In particular the parameter value populations of different generations are installed electrically in parallel to one another and/or deposited next to one another. It is also possible to deposit several generations above one another and subsequently next to one another. For example, when a maximal practicable number of deposits above one another is reached, a next generation can be deposited next to the existing generations and all following generations above one another, in order to fully utilize the substrate area or in order keep initial measurement conditions.

In a further development of the invention, the electrical characteristic is the electrical conductivity, the temporal change of the electrical conductivity, or the electrical capacity of the respective layer or possibly of the layers deposited as a parallel circuit or connection. In particular, the temporal change of the electrical conductivity is taken into account for the optimization evaluation through the genetic algorithm. By using the temporal change or increase of the conductivity, the setting process can be accelerated since parameter values for which a large increase in conductivity occurs can quickly lead to larger electrical conductivities.

In a further development of the invention, for determining the electrical characteristic of the respective layer, an electrical measurement value is gathered by a measurement device and/or a temporal change of an electrical measurement value of the layers, possibly deposited in parallel to one another, is detected by the measurement device. In particular when no time course or time behavior of the measurement value is gathered, the electrical characteristic can possibly be detected from the difference of the measurement value of a prior gathering and the measurement value of the respective layers deposited in parallel.

In a further development of the invention, prior to depositing a first parameter specific layer of the first generation parameter value population, a conductive base layer such as a Seed-Layer is deposited. Through these means it is ascertained that, even when beginning the method, a sufficiently large conductivity for performing the measurement of the electrical characteristic of the first layer is provided.

According to a further aspect of the invention, in a method for setting a deposition system, the method according to the first aspect is applied in order to find an optimized parameter value for at least one setting parameter of the deposition system, and the deposition system is set in accordance with the found optimized parameter value for the at least one setting parameter.

According to a last aspect of the invention, the deposition system for depositing an electrically conductive layer, preferably having a layer of less than 20 nm, comprises a gas injection system for providing a precursor, an electron beam generator or ion beam generator, an electronic device or electronics for finding at least one setting parameter of the depositing system optimized with respect to an electrical target characteristic of the conductive layer, wherein the electronics comprises at least one control output for the at least one setting parameter for the deposition system, and a measurement device connected to the electronics for detecting an electrical characteristic of the layer, wherein the electronics is configured for performing a genetic algorithm such that several parameter values of at least one setting parameter are determined for defining a first generation parameter value population for depositing a layer for each parameter value by means of the deposition device, each parameter value of the first generation parameter value population being set at the control output and possibly at least one further setting parameter of the deposition system being kept constant; an electrical characteristic for each layer of each parameter value of the first generation parameter value population being detected; optimization evaluation of the detected electrical characteristics with respect to the electrical target characteristic being performed, and, based on the optimization evaluation, a further second generation parameter value population being determined; and, under the premise of using the parameter values that are being used for the second or a possibly further generation of a new parameter values, each parameter value of the parameter value population being set at the control output until the electrical target characteristic is reached or until the genetic algorithm is concluded for a generation predetermined to be the last generation.

Preferably, the parameter values are set after one another at the at least control output, wherein, after depositing a layer, the respective at least one control output is set to the next parameter value.

In particular, the device is configured for performing the method according to the invention or according to a further development of the method according to the invention.

It has been shown that the method according to the invention can also be utilized for depositing superconductive layers. Surprisingly, with the application of the method according to invention under the premise of the electrical target characteristic being a large specific conductivity, optimized parameter values were achieved such that the deposited layer has a large transition temperature towards superconductivity.

The invention also relates to a method for depositing a superconductive layer onto a substrate. The deposited layer can be used as superconducting nanostructure. In the method, a precursor gas is used which comprises superconductive material which has been brought into the gaseous phase. The substrate is subjected to the precursor gas and subjected to an electron beam or ion beam so that, under interaction of the precursor gas with the electron beam or ion beam, the superconductive material is deposited onto the substrate.

Preferably, the mask-free single-level or single-state Direct Write technology is applied by use of the electron beam or ion beam in which the layer properties, such as composition, structure or thickness, can be set by adapting the movement parameters of the electron beam or ion beam without having to interrupt the writing procedure. In particular the method according to the invention is performed according to the principle of focused electron beam-induced deposition (FEBID) or focused ion beam-induced deposition (FIBID). Superconductive material can thereby be brought into the gaseous phase through sublimation for providing the precursor gas, in particular a metal organic gas. Materials that have an electrical resistance which is reduced to zero upon falling below a transition temperature can be understood to be superconductive. It shall be clear that the superconductive material does not need to be superconductive during all steps of the method, in particular not while it is present in its gaseous phase as a component of the precursor gas.

The substrate forms a layer carrier on which for instance the access to the electrical connections of the layer occurs. The substrate can be manufactured by forming several layers having different material properties and by using and combining several materials, such as metals, polymers, glass or semiconductive materials. For instance a particularly n-doted silicon comprising substrate can be used as substrate. In particular, the substrate and the precursor gas are subjected to an underpressure with respect to the atmosphere. Preferably, the electron beam or ion beam is focused for instance using a lens-system and can be moved over the substrate according to a raster which is in particular laid out in at least two dimensions. On the surface of the substrate, superconductive material absorbed from the precursor gas is dissociated or under the influence of the particularly focused electron beam or ion beam so that superconductive material is put onto the substrate.

Preferably when performing the method, a gallium-ion-beam is used, wherein the beam current is less than 100 pA, in particular less than 50 pA, preferably between 5 pA and 20 pA, and/or wherein an accelerating voltage is set to between about 1 kV and 60 kV, in particular between 20 kV and 40 kV.

In a preferred embodiment the superconductive material is metallic, in particular a transition metal such as molybdenum. Preferably molybdenum hexacarbonal (Mo(CO)₆) is used as precursor gas.

Preferably at least one method parameter, such as an electron beam-parameter or ion beam-parameter, in particular the raster position dwell time and/or the raster pitch in at least one direction of movement of the electron beam or ion beam, can be optimized according to the method for optimizing the positioning process according to the invention as described above. In particular, the optimization cycle is performed prior to performing the deposition method.

The method according to the invention allows depositing a multitude of layers having different characteristics onto a layer carrier without much effort. Electrical properties of the deposited layer can thereby be set by varying the material which forms the non-volatile, settling down fractions of the precursor gas, or by changing different method parameters such as substrate-temperature, precursor gas stream or beam parameters. Surprisingly, when using a superconductive material for the precursor gas, the method according to the invention creates a superconductive layer onto the substrate, having a transition temperature significantly above the transition temperature of the superconductive material itself. In particular significantly large increases in the transition temperature could be achieved in case at least one method parameter, in particular the raster pitch and the raster dwell time, were detected in advance with the aid of the optimization method according to the invention. It has been shown that by specifying a large specific electrical conductivity as an evaluation criterion, even surprisingly large density of electronic states of the deposited material could be achieved from which the increased transition temperature of the deposited layer results.

The invention further relates to an electrically conductive, preferably superconductive, layer which can be manufactured by focused electron beam- or ion beam-induced deposition under application of the optimization method according to the invention or under application of the deposition method according to the invention. Through the application of the optimization steps during the deposition process in particular under the specification of a maximal electrical conductivity of the layer as evaluation criteria, the chemical composition of the deposited layer is adjusted. Unexpectedly, the layers resulting under optimization of the setting parameters, in particular the raster dwell time and the raster pitch, displayed large transition temperature towards superconductivity. Furthermore, a conductive, in particular superconductive, layer according to the invention can be manufactured by applying the deposition method by means of the above-mentioned deposition method as described above. Thereby a precursor gas comprising a superconductive material which has been brought to its gaseous phase is stimulated with an electron beam or ion beam, in particular a gallium ion beam. The method parameters are set such that in the light of experience a large electrical conductivity or electrical density state of the deposited layer is achieved. Preferably the setting parameters are set with the aid of the optimization method according to the invention.

According to a preferred embodiment, the electrically conductive layer includes carbon and gallium with a summed or sum atom percentage fraction of about 60 at % or less, in particular about 55 at % or less, preferably about 52 at % or less. In particular, the carbon fraction is larger than 15 at % and the gallium fraction is smaller than 35 at %. In particular, the carbon fraction and the gallium fraction are essentially equal. In particular, the layer comprises a metal fraction, in particular a transition metal fraction, such as a molybdenum fraction, of at least 30 at %, in particular at least 35 at %, preferably at least 40 at %. In particular, the layer comprises an oxygen fraction of less than 20 at %, in particular less than 15 at %, preferably less than 10 at %.

Further properties, advantages and features of the invention will be described in the following description of preferred embodiments based on the attached figure, in which is shown:

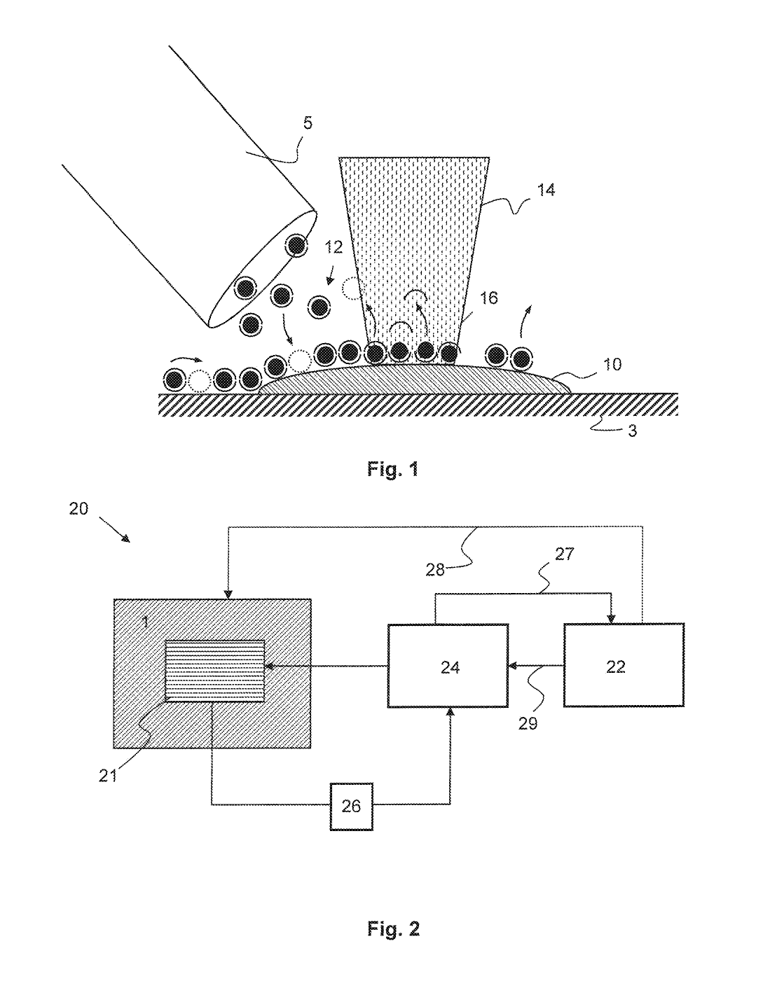

FIG. 1 a schematic illustration of a deposition method;

FIG. 2 a schematic illustration of a deposition system according to the invention;

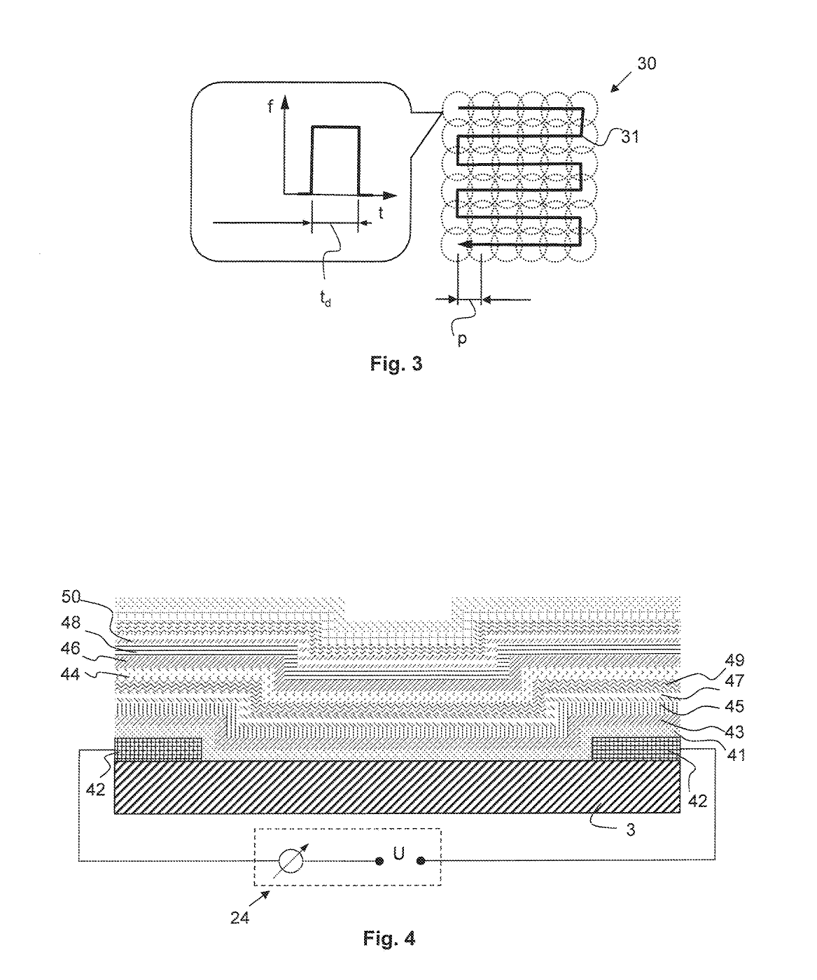

FIG. 3 a schematic illustration of an exemplary embodiment for a movement raster of the electron beam or ion beam in the deposition system according to the invention and a sketch of an irradiation diagram for a position of the raster.

FIG. 4: a schematic illustration of a deposition of multiple conductive layers on a substrate after conducting the method or performing the device according to the invention;

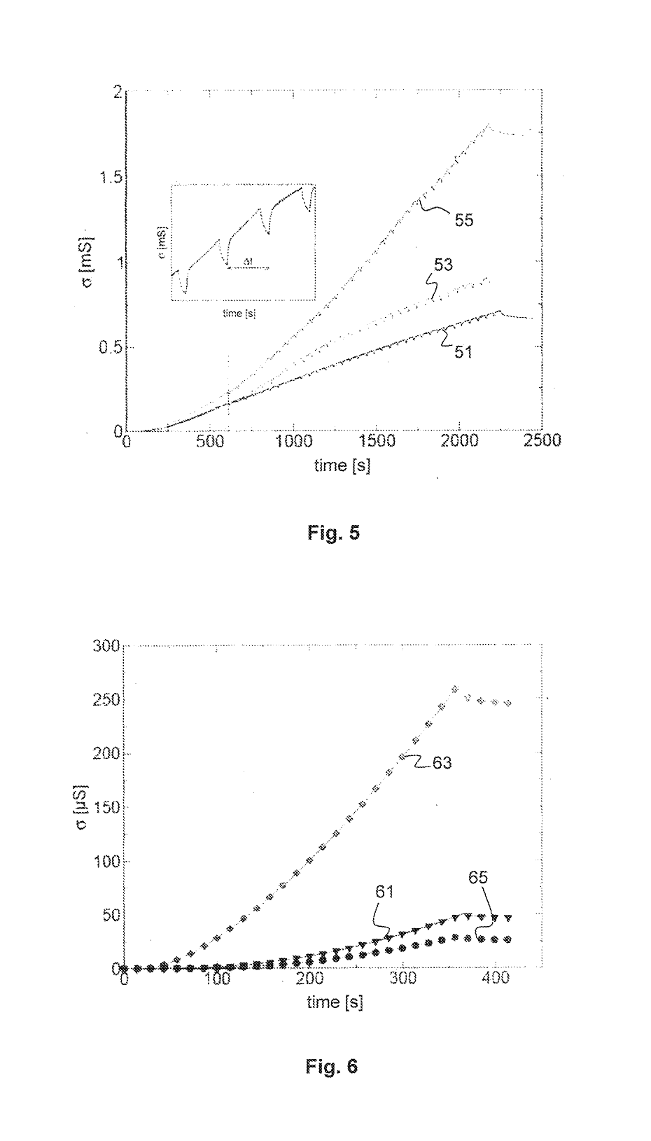

FIG. 5: a conductivity-time-diagram according to an exemplary embodiment of the invention which illustrates the change of a setting parameter according to the invention;

FIG. 6: a conductivity-time-diagram illustrating the conductivity-course for three deposition methods;

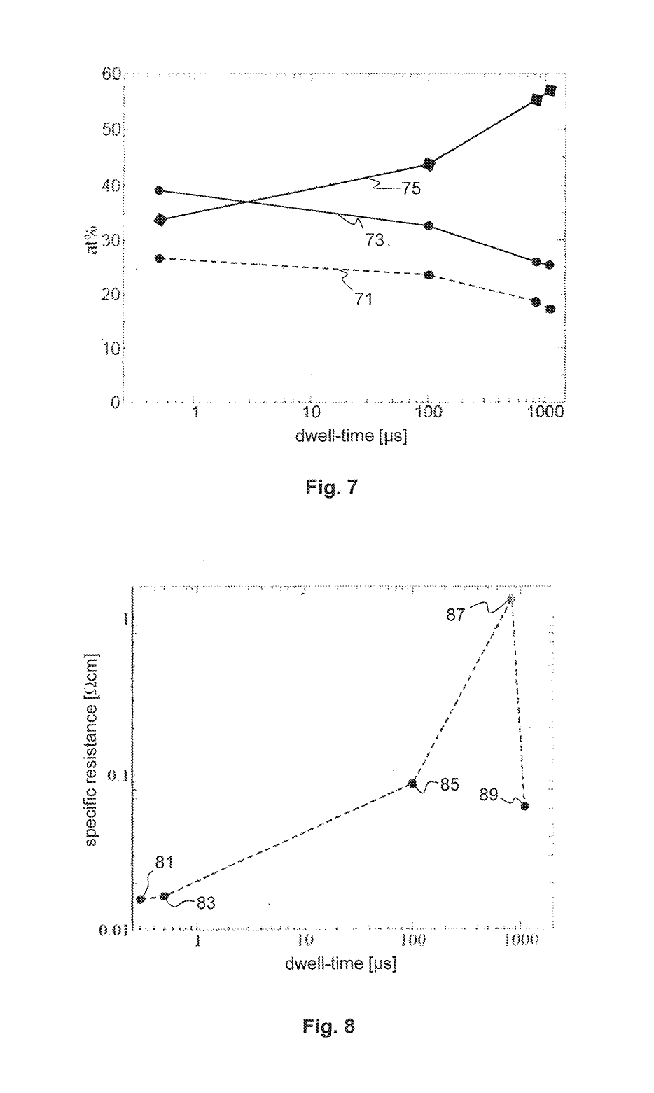

FIG. 7 a diagram for illustrating different chemical compositions of deposits or depositions under the application of the optimized positioning method and deposition methods which are not optimized.

FIG. 8 a diagram that exemplarily illustrates the dependency of an electrical characteristic of a deposit from one setting parameter to be optimized according to the invention;

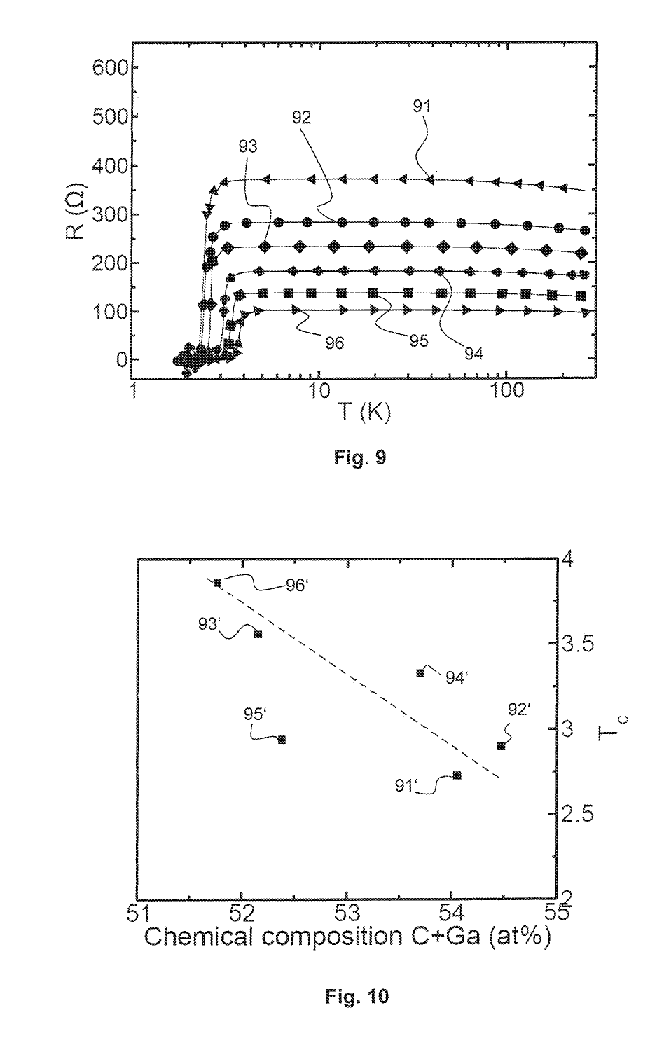

FIG. 9 a diagram which exemplarily illustrates the superconductivity for superconductive layers manufactured with different method parameters according to the method according to the invention.

FIG. 10 a diagram which exemplarily illustrates the transition temperature depending on the gallium- and carbon-fracture for different superconductive layers manufactured according to the method according to the invention with different method parameters; and

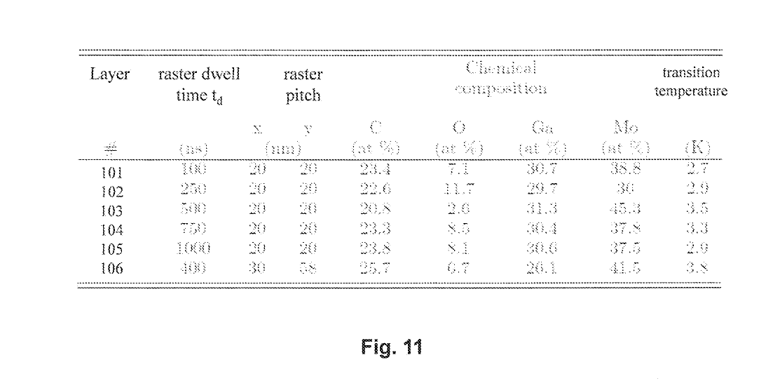

FIG. 11 a chart illustrating the chemical composition as well as the method parameters raster dwell time and pitch for six electrically conductive layers according to the invention.

FIG. 1 schematically shows as an example for one embodiment of the invention the deposition method to be optimized inside a vacuum chamber of a raster electron microscope (not illustrated in detail) in which a substrate 3 is provided which for instance consists of a silicon, another semiconductor, a metal, polymer or insulator. By means of a gas injection system 5, a metal organic gas, such as tungsten-hexacarbonyl, is inserted into the vacuum chamber as precursor 12. A focused electron beam 14 strikes a limited area of the substrate 3. Within the focus of the electron beam, the precursor 12 is dissociated or decomposed. During the dissociation, non-volatile components 16 of the precursor form an electrically conductive deposit 10 on the substrate 3. Volatile waste products of the dissociation process are evacuated from the vacuum chamber through a vacuum pump system of the raster electron microscope which is not illustrated in detail. In order to form a dimensionally spatially defined, coherent, electrically conductive layer on the substrate 3, the electron beam 14 is moved in a predetermined raster over the substrate 3. In the focus of the electron beam 14, further non-volatile components 16 are deposited and in particular accumulated in the height, in areas in which non-volatile components 16 have already been deposited onto the substrate 3.

In place of the electron beam 14, also a focused ion beam, such as a gallium-, helium-, or neon-ion beam can be realized in order to initiate the decomposition or dissociation of the precursor 12 according to similar principles.

The electrical properties of the conductive layer on the substrate can be influenced through different setting parameters specific to the deposition procedure. Some of these parameters are electron beam-parameters or ion beam-parameters, such as the accelerating voltage with which the electrons or ions are shaped to a beam, the current provided for forming the beam, the raster pitch of the beam in x-direction and y-direction, the raster position dwell time, also referred to a dwell-time t_{d}, and the rate of raster repetition, in case the raster is passed through for several times while depositing the layer. Furthermore, the deposition procedure can be adapted through the chemical composition of the precursor, the precursor gas stream and/or the temperature of the substrate.

As shown in FIG. 2, the embodiment of the invention is provided with a deposition system 20 comprising a raster electron microscope 1, a measurement device or measuring device 24 as well as an electronic device or electronics 22. The electronics 22 is firstly configured in view of the setting parameters to be optimized. The optimization target, for instance reaching a maximal conductivity of a created layer, is also set. In particular the optimization target is filed in the electronics in the form of an evaluation criterion, the so called fitness-function for the genetic algorithm. Surprisingly it was shown that, at a particular setting parameter, namely the raster position dwell time or dwell-time t_{d}, particularly large increases in conductivity can be achieved by means of the genetic algorithm. With simultaneous optimization of multiple setting parameters of the system the effort of the experiment for finding settings for the desired electrical properties are essentially reduced in proportion to the number of setting parameters to be optimized since sequential testing can be avoided.

The measuring device 24 is in particular a source meter and is electrically connected with the sample 21 arranged within the raster electronic microscope so that a measuring voltage can be applied to the sample. The measuring device 24 gathers a measuring current related to the predetermined measurement voltage so that the electrical resistance and the electrical conductivity of the layers deposited onto the sample can be detected. For guarding the isolated layers, a bypass and/or a ground box 26 is connected between the measuring device 24 and the sample 21. The voltage value predetermined by the measurement device 24, and the given current value are transmitted via the communication conduit 27 for storing and further processing by the electronics. Naturally, the measuring device can be configured for gathering other evaluation criterions such as the capacity of the sample. The electronics 22 can set the frequency or the point in time for gathering electrical characteristics through the measurement device via communication conduit 29.

As illustrated in FIG. 3, when depositing, the electron beam 14 is led along a raster 30 on a snakelike or serpentine beam path 31 over the substrate 3. At each raster position, the electron beam 14 stays or dwells for the dwell-time t_{d} which is set equal for all raster points or raster positions. For depositing a conductive layer, the electron beam circles or moves repeatedly along the same beam path 32 over the same positions of the substrate. The respective points of the raster 30 are arranged with a respective distance P from one another, the so called pitch. On the left side it is shown that during the beam dwell-time t_{d} at the respective raster point, a large electron beam intensity F occurs, wherein earlier and later the electron beam intensity is essentially zero, which can be attributed to the focusing of the electron beam and which allows for determining these spatial extension of the layers particularly precisely in the nanometer range.

Furthermore, optimizing the deposition procedure according to the invention is described on the basis of an example. First, a substrate 3 is provided at a certain temperature, which also influences the result of the deposition. Therefore, the deposition system comprises a temperature controller which is not illustrated in detail. The substrate temperature can be a setting parameter to be optimized. As shown in FIG. 4, the substrate 3 comprises two measuring electrodes 42, in particular gold electrodes, which are connected to the measuring device 24. For providing an initial conductivity between the measuring electrodes 42, at first a base layer 41, the so called Seed-Layer, is deposited on the substrate 3.

Afterwards, the electronics 22 is configured such that the setting parameter to be optimized is the dwell-time t_{d} The maximal electrical conductivity of the layer is specified the optimization target. The method is to be aborted when the electrical conductivity signal reaches at least 2 mS or when the genetic algorithm is concluded for the 30^{th} generation of parameter value populations. All further setting parameters are constant values which are known to be expedient. However, with the method several setting parameters can readily be optimized simultaneously.

The electronics 22 at the beginning of the optimization determines a number n of parameter values t_{d1}¹, t_{d2}¹, . . . t_{dn}¹ for the dwell-time to be optimized and thus defines a first generation parameter value population for the genetic algorithm. The number n corresponds to the size of the population and can be preconfigured. The parameter values t_{d1}¹, t_{d2}¹, . . . t_{dn}¹ can be randomly assigned or from the storage of electronics 22 with values which are known to make sense.

The electronics 22 sets the dwell-time via the control output 28 at the deposition system 20 to the first parameter value t_{d1}¹ of the first generation population. The deposition system deposits a first parameter value specific layer. After depositing the first layer, which can be communicated to the electronics via a status signal of the deposition system, the electronics 22 sets the setting parameter to the following value parameter t_{d2}¹ of the first generation population, and the deposition systems deposits a second parameter value specific layer. This procedure is repeated for all parameter values of the first generation population. The electronics 22, during the deposition and/or at defined points in time after the deposition, determines with the aid of a measurement device 24 the electrical conductivity σ₁¹, σ₂¹, . . . σₙ¹ of the respective layer. The electronics calculates from these the rate of change σ″₁¹, σ″₂¹, . . . σ″ₙ¹ of the electrical conductivity. Afterwards, according to a genetic algorithm, the parameter values t_{d1}¹, t_{d2}¹, . . . t_{dn}¹ are evaluated based on the respective increase of the rate of change σ″₁¹, σ″₂¹, . . . σ″ₙ¹ of the electrical conductivity corresponding to the layers, taking into account the optimization target, maximal electrical conductivity, in particular those parameter values which have led to layers having a high conductivity, for instance t_{d1}¹, t_{d2} and t_{d3}¹ are selected according to a scheme of selection, varied according to a scheme of recombination to further parameter values t_{d1*2}¹, t_{d1*3}¹, t_{d2*3}¹, t_{d2*1}¹, and are mutated, and from these parameter values t_{d1}², t_{d2}¹, . . . t_{dn}² a second generation parameter value population is determined. Then the electronics 22 provides, via the control output 28 of the deposition system 20, the dwell-time to the first parameter value t_{d1}² of the second generation population, and the deposition system deposits a first parameter value specific layer of the second generation. Then a measurement period commences, and the procedure is repeated for all second generation parameter values, until the electronics 22 once more evaluates the parameter values according to the genetic algorithm based on the respective increase and rate of change σ″₁², σ″₂², . . . σ″ₙ² of the detected conductivities of the layers of a second generation, and determines a next generation parameter value population. The electronics 22 deactivates the deposition systems as soon as the electrical target conductivity is reached or as soon as the evaluation of the 30^{th} generation is concluded.

In FIG. 4, a conductor structure is schematically illustrated for a population size of four, in which the layers are deposited one above another. On the substrate, above the Seed-Layer or base layer 41, four layers 43, 45, 47, 49 are deposited one above another. After executing the genetic selection and determining four further parameter values, four depositing layers 44, 46, 48, 50 have been sequentially deposited above the already existing layers. Further layers which are created by commencing the method, are only hinted at.

FIG. 5 shows as an example, a function of conductivity of a deposit during operation of the deposition system or during application of the optimization method according to the invention, and a function of conductivity according to a prior art deposition procedure. The function or curve of conductivity 51 results from the operation of a common deposition system with constant setting parameters based upon experience values. In the illustrated course of time, little by little, further layers are laid upon one another onto the substrate in order to form a conductor structure. During the operation of the deposition system with parameters set to constant, an increase of conductivity results, which is essentially linear to the number of layers. As illustrated in detail in the increased section, a saw tooth form of the course of conductivity results. Each respective slight drop of conductivity is formed during the short deposition-intermissions between the deposition of the individual deposit layers. The function of conductivity 55 was achieved through an exemplary execution of the method according to the invention, in which the dwell-time was varied in an value range of 0.2 μs to 1500 μs with otherwise constant parameters. The third function of conductivity 53 is reached by means of the invention when the genetic algorithm is used in the reversed sense, that is, for detecting parameter values for creating layers having the least possible amount of conductivity. In this case, three setting parameters were varied simultaneously using the method according to the invention, the dwell-time within a value range of 0.2 μs to 1500 μs, as well as the raster point distance in x-spatial direction within a value range of 35 nm to 200 nm, and the raster point distance in a vertical y-spatial direction perpendicular to the first spatial direction in a value range between 30 nm and 200 nm. The remaining parameters are constant for all three illustrated functions of conductivity, namely the accelerating voltage, the electron beam 5 kV and beam current 1.6 nA, 23° C. substrate temperature as well as gas stream of the precursor. In FIG. 6, three functions of conductivity 61, 63, 65 are illustrated during deposition, when the execution takes place according to the method for setting a deposition system according to the invention. The function 61 was recorded during the deposition of a deposit using standard settings based on the experience for the influence factors dwell-time t_{d} and raster distance p. The function 61 serves as a reference for comparing to the functions of the conductivity which are achieved through operation parameters which were found by operation of the optimization method according to the invention. For function 61, the standard values t_{d}=100 μs and p=40 nm are taken into consideration. By application of the invention, for a specific deposition system it was detected that a particularly large increase in conductivity can be achieved when the dwell-time is set to 0.3 μs and the raster distance is set to 40 nm, as shown with function 63. According to FIG. 6, by application of the method according to the invention, conductivity of the deposit five times larger in comparison to the reference function 61 is achieved. The further systems specific influence factors are constant with respect to the functions 61, 63, 65. The method according to the invention also allows for finding parameter values with which the conductivity of the deposit can be set to be particularly low. This is illustrated in curve 65, which was achieved with a dwell-time of 837 μs and a raster distance in a first raster direction of 35 nm, and the raster distance in a second raster direction are perpendicular to the first raster direction of 150 nm. For achieving a low conductivity in an optimization process using the genetic algorithm, preferably such parameter values are inherited to the next generation, which lead to a least possible increase in the rate of change of conductivity during the deposition process of the layer. The large increase seen in FIG. 6 results from the different chemical compositions during the deposition, in particular to the metal fraction which is increased by 15% from function 63 with respect to the function 65 and/or from different micro- and/or nanostructures of the layers which can be influenced by the dwell-time and pitch.

In FIG. 7, the atomic percentage composition of four different deposits (indicated by measurement points) is illustrated in dependence of the dwell-time t_{d}, wherein the dashed curve shows the oxygen fraction 71, the continuous line marked with dots indicates the tungsten fraction 73, and the solid line marked with diamonds indicates the carbon percentage 75. From the course of the function can be read that a shorter dwell-time leads to an increase of the tungsten fraction up to 40 atom percent. The increased metal fraction at short dwell-time supports the observed increase of conductivity.

FIG. 8 illustrates the specific resistance for deposits having a certain dwell-time. While at short dwell-times, as indicated by measurement points 81, 83, a small specific resistance of the deposit is achieved, this increases the dwell-time according to measurement point 85 and becomes maximal at the dwell-time which, according to the genetic algorithm, has the least increase in conductivity at the measurement point 87. At dwell-time of 837 μs and a raster distance in x-direction of 35 nm and a raster distance in y-direction of 150 nm, the specific resistance becomes maximal. With an equal raster distance of about 40 nm in x- and y-direction, a comparatively low specific resistance can be achieved with a large dwell-time, as shown with measurement point 89. According to the invention, the specific resistance of the deposited layers can be increased by magnitudes through optimizing the setting parameters dwell-time and pitch when using the precursor tungsten hexacarbonyl.

According to the invention, the setting parameters of the deposition system can be optimized, so that an electrical conductance of the deposit to be formed in the system achieves the desired values in a significantly reduced amount of time than before. By applying a genetic algorithm with a direct experimental feedback through in-situ measurements, a large amount of parameters, the interdependencies of which are not accessible by means of simulation models, can be set to optimized parameter values leading to the desired deposit.

In FIG. 9, the electrical conductance R of six different superconductive layers is charted with respect to the temperature. Each respective charted curve function 91, 92, 93, 94, 95, 96 shows the resistance of a respective layer which was deposited onto a semiconductor substrate according to the method according to the invention. For all examples, molybdenum hexacarbonyl Mo(CO)₆ was used as precursor. However, the method according to the invention, in particular the further application of the optimization method according to the invention, can also create superconductive layers using other precursor gases having a larger transition temperature than the deposition material provided as precursor gas. While the transition temperature of the molybdenum itself is about 0.92 Kelvin, the layers deposited according to the invention achieve transition temperatures between 2.7 and 3.8 K. The largest transition temperature is shown by the layer of function 96. The parameter values, which were used for the setting parameter dwell-time (T_{D}) as well as pitch in X- and Y-direction, which were used when depositing this layer were optimized by means of the above described method for optimizing a deposition process in advance. As an evaluation criterion or electrical target characteristic, the maximum electrical conductivity was specified.

In FIG. 10, the transition temperature for the same layers whose resistance-function are illustrated in FIG. 9 are brought into contest with the respective sum- or summed-fraction of carbon (C) and gallium (Ga) of the deposited layer. The reference points 91′, 92′, 93′, 94′, 95′, 96′ indicate the sum fraction of the layer which is to be associated with the respective measurement curve 91, 92, 93, 94, 95, 96. According to the dashed trend-line, the transition temperature increases with a decreasing sum-atom-percentage of carbon and gallium.

Surprisingly, it was shown with the aid of the optimization method, the parameter values of setting parameters of the deposition process are optimized under the evaluation criterion of maximal electrical conductivity such that the resulting electrically conductive layer has a significantly increased transition temperature towards superconductivity than layers deposited with another method and/or without optimized parameters.

FIG. 11 shows a chart in which, for the layers according to FIGS. 9 and 10, the adapted method parameters, the transition temperature, as well as the chemical composition are arranged. Other method parameters than the illustrated ones were kept constant. Measurement function 91 and measurement point 91′ correspond to layer 101, measurement function 92 and measurement point 92′ correspond to layer 102, and so on. Layer 106, which has the largest transition temperature of 3.8 Kelvin, has essentially equally large atom percentage fractions of carbon and gallium, namely about 26 at %, in particular a carbon fraction of 25.7 at % and a gallium fraction of 26.1 at %. The molybdenum fraction amounts to more than 41 at %, in particular 41.5 at %. The setting parameter raster dwell-time t_{d} and raster pitch in x- and y-direction were determined by means of the method according to the invention by applying the genetic algorithm. As can be seen, changes of the setting parameters of the depositing procedure, when conducting the described optimization method or the depositing method, influence the chemical composition of the electrically conductive layer, and of the transition temperature towards superconductivity. All of the layers formed according to the deposition method according to the invention (layers 101, 102, 103, 104, 105, 106) exhibit in a transition temperature of at least 2.7 Kelvin. The largest transition temperature of about 3.8 Kelvin is achieved by layer 106 which was deposited with the optimization method according to the invention.

The features disclosed in the above description, in the figures and in the claims can be of relevance both individually as well as in any combination thereof for realizing the invention in the different embodiments.

### REFERENCE NUMERALS

3 substrate
5 gas injection system
10 deposit
12 precursor
14 electron beam
16 non-volatile components
20 deposition system
21 sample
22 electronics
24 measurement device
26 ground box
27, 29 communication conduit
28 control output
30 movement raster
31 beam path
41 base layer
42 measuring electrodes
43, 45, 47, 49 parameter specific first generation layer
44, 46, 48, 50 parameter specific second generation layer
51, 53, 55, 61, 63, 65 curve of conductivity
71 oxygen fraction
73 tungsten fraction
75 carbon fraction
81, 83, 85,87, 89, 91′ measurement points
92′, 93′, 94′, 95′, 96′ measurement points
91, 92, 93, 94, 95, 96 measurement curve
101, 102, 103 layers
104, 105, 106 layers
p raster pitch
t_{d} dwell-time

What is claimed is:

1. A method for optimizing a deposition process for creating an electrically conductive layer preferably having a layer thickness of less than 20 nm by means of an electron beam-induced or an ion beam-induced deposition system, comprising the steps:
a. Selecting at least one deposition-specific setting parameter to be optimized, such as an electron beam-parameter or an ion beam-parameter of the deposition system;
b. Determining several parameter values of the at least one setting parameter for defining a first generation parameter value population;
c. Depositing a layer for each parameter value of the first generation parameter value population by means of the deposition system;
d. Detecting an electrical characteristic for each layer of each parameter value of the first generation parameter value population;
e. Using a genetic algorithm which executes an optimization evaluation of the detected electrical characteristics with respect to a predetermined electrical target characteristic and, based on the optimization evaluation, determines a further second generation parameter value population; and
f. Repeating steps c. through e. by using parameter values of the second generation or a further generation, until the electrical target characteristic is reached or until the genetic algorithm is concluded for a generation predetermined to be the last generation.

2. A method according to claim 1, in which the at least one setting parameter is selected from a group comprising: an accelerating voltage of the electron beam or the ion beam, a current of the electron beam or the ion beam, a defocus of the electron beam or the ion beam, a raster pitch (p) of a movement raster of the electron beam or the ion beam, a raster position dwell time (t_{d}), a rate of raster position repetition, a temperature of a substrate onto which the layers are deposited, a precursor gas stream, and, a chemical composition of a precursor under the decomposition of which the layers are deposited.

3. A method according to claim 1, wherein the parameter value-specific layers of a respective parameter value population and/or the generations of parameter value populations are deposited electrically in parallel to one another.

4. A method according to claim 1, wherein the parameter value-specific layers of a respective parameter value population and/or the parameter value population are deposited one above the other.

5. A method according to claim 1, wherein a respective layer is deposited between two measuring electrodes and/or wherein a respective parameter value population is deposited between two generation-specific measuring electrodes.

6. A method according to claim 1, wherein the electrical characteristic is the electrical conductivity (σ), the temporal change of the electrical conductivity (σ) or the electrical capacity of a respective layer or of layers deposited as a parallel circuit.

7. A method according to claim 1, wherein for detecting the electrical characteristic of a respective layer an electrical measurement value is gathered by a measurement device and/or a time course of an electrical measurement value of the layers.

8. A method according to claim 1, wherein prior to depositing a first parameter specific layer of the first generation parameter value population a conductive base layer deposited.

9. A method for setting a deposition system, wherein the method of claim 1 is applied for finding an optimized parameter value for at least one of the setting parameters of the deposition system and wherein the deposition system is set according to the found optimized parameter value for the at least one setting parameter.

10. A deposition system for depositing an electrically conductive layer preferably having a layer thickness of less than 20 nm, comprising a gas injection system for providing a precursor, an electron beam generator or an ion beam generator, electronic means for finding at least one setting parameter optimized with respect to an electrical target characteristic of the conductive layer, such as an electron beam parameter or an ion beam parameter, wherein said electronic means includes at least one control output for the at least one setting parameter of the deposition system and a measurement device connected to said electronic means for gathering the electrical characteristic of the layer, wherein said electronic means is configured for performing a genetic algorithm such that:
several parameter values of the at least one setting parameter are determined for defining a first generation parameter value population;
for depositing a layer for each parameter value the deposition system, each parameter value of the first generation parameter value population is set at the control output;
an electrical characteristic is detected for each layer of each parameter value of the first generation parameter value population;
an optimization evaluation of the detected electrical characteristics is performed with respect to the electrical target characteristic, and based on the optimization evaluation a further second generation parameter value population is determined; and,
finding the parameter is continued by utilizing the parameter values of the second generation or a further generation, until the electrical target characteristic is reached or until the genetic algorithm is concluded for a generation predetermined to be the last generation.

11. A method for depositing a superconductive layer onto a substrate, wherein
a precursor gas comprising a superconductive material brought into the gaseous state is utilized;
the substrate is subjected to the precursor gas; and
the substrate is subjected to an electron beam or an ion beam such that the superconductive layer is deposited onto the substrate under interaction of the precursor gas and the electron beam or the ion beam.

12. A method according to claim 11, characterized in that the material is a metal, particularly a transition metal, such as molybdenum, and/or in that the precursor gas comprises at least one further gas component, such as carbon and/or oxygen.

13. A method according to claim 11, characterized in that at least one method parameter, such as an electron beam-parameter or an ion beam-parameter, is set according to the optimization method of claim 1.

14. An electrically conductive layer, particularly a superconductive layer which can be manufactured by a focused electron beam-induced deposition or a focused ion beam-induced deposition using the optimization method according to claim 1 or using the deposition method according to claim 11.

15. An electrically conductive layer according to claim 14, comprising carbon and gallium having a summed atomic percentage fraction of about 60 at % or less, in particular about 55 at % or less, preferably about 52 at % or less, wherein in particular the carbon fraction is more than 15 at % and the gallium fraction is less than 35 at %, and/or wherein the layer comprises a metal fraction, in particular a transition metal fraction, such as a molybdenum fraction, of at least 30 at %, in particular at least 35 at %, preferably at least 40 at %, and/or wherein the layer comprises an oxygen fraction of less than 20 at %, in particular less than 15 at %, preferably less than 10 at %.
